(19) United States
(12) Patent Application Publication
(10) Pub. No.: US 2026/0313887 A1
(43) Pub. Date: Oct. 8, 2026

(54) INTEGRATED CIRCUIT WITH HARD-CODED IC-SPECIFIC CODE, DEVICE AND METHOD

(71) Applicant: Sandgrain B.V., Eindhoven (NL)

(72) Inventors: Pieter Werner HOOIJMANS, Eindhoven (NL); Casparus Anthonius Henricus JUFFERMANS, Eindhoven (NL); Jeroen Mathias DOUMEN, Eindhoven (NL)

(21) Appl. No.: 19/476,203

(22) PCT Filed: Apr. 17, 2024
(86) PCT No.: PCT/IB2024/053766

§ 371 Date: Oct. 17, 2025

(30) Foreign Application Priority Data
Apr. 18, 2023 (NL) 2034620

(51) Int. Cl. H10B 20/00

(52) U.S. Cl. CPC H10B 20/34

(57) ABSTRACT

integrated circuit having a predetermined IC-specific N-bit binary code hard-coded into the structure of the integrated circuit, with a plurality of logic voltage lines; N identical bit circuits, each adapted to generate one bit of the N-bit code, the bit circuits formed in a plurality of first layers of the IC. Each bit circuit comprises an input and an output; N identical pull-down circuits connecting an input of one of the N bit circuits to one of the logic voltage lines. The pull-down circuits are formed in the first lower layers and a plurality of programmable connections formed above the first lower layers. programmable connections electrically connect an input of a selected set of the bit circuits to one of the logic voltage lines. electrical connections with the bit circuits and the pull-down circuits, hard-code the IC-specific N-bit binary code into the integrated circuit.

### TECHNICAL FIELD

The present invention relates to an integrated circuit having an IC-specific code which is hard-coded into the structure of the integrated circuit, in particular so as to form a trust anchor in secure systems.

### BACKGROUND ART

Such a secure system is e.g. pre-published by patent publication WO2021240445, which discloses the use and definition of a trustworthy chip, typically for an end node, which can thereby be identified, preferably also authorized, using a central registration system or server, and encrypted communication. A chip, i.e. electronic device as defined by this publication, thereto comprises a pre-determined, preferably hard coded, immutable secure element, which apart from an identification value, may contain various codes such as a customer code, and which comprises one or more keys or headers for enabling encrypted communication with the central server, thus forming a trust anchor as it were in the secure system, e.g. as defined by this publication. One object of the present invention is involved with realizing a generic design of a semi-conductor device which may be programmed for this purpose as known per se.

One example of a semi-conductor device of the ROM or read only memory type, having an electric circuit which may subsequently, i.e. after manufacture of the chip, be programmed is known from patent publication US20060119415, which suggests a circuit, of which a value may be electrically altered using a laser irradiation for blowing fuse elements in the circuit. The circuit is however not useable for the present purpose since it comprises an electrical switch SET and an activation input for a so-called pre-charge signal. Such programmable signal facilities of the known chip are ideal for repairing, at least rescuing any defective memory cells of the device, however render the design useless for application in a secure element or device as referred to in the preceding. Alternatively denoted, this prior art in fact sets forth a RAM cell that is put in a fixed mode, viz. value 1 or value 0. This known set-up requires a select line, or in general, requires electrical support, here denoted PRC. The system thus proposes an electronically controlled circuit, which is the opposite of what is endeavored in the presently proposed subject and invention.

The present invention hence seeks to render a generally useable, at least secure circuit design that enable a one time programming of the circuit in an immutable manner.

In a general approach of the object of the present invention, it is observed that conventional Read Only Memory (ROM) can store a hard-coded non-erasable and non-changeable code are mostly based on special floating gate MOS-transistors. They are essentially a matrix of N×M transistors, e.g. for storing N words of M bits. Programming is done during manufacture of the device, by connecting a transistor at selected cross points of the matrix. A connected cross-point generates a logical “1”, while a non-connected cross-point generates a logical “0”. This usually done at low metal layers in the technology stack, typically at metal layer 3 (M3) or 4 (M4). This means that the code to be stored in the ROM must be known before producing the IC, and the code is fixed in a so-called ROM-mask. Therefore, there is no way that classical ROMs can be used in combination with individual chip programming.

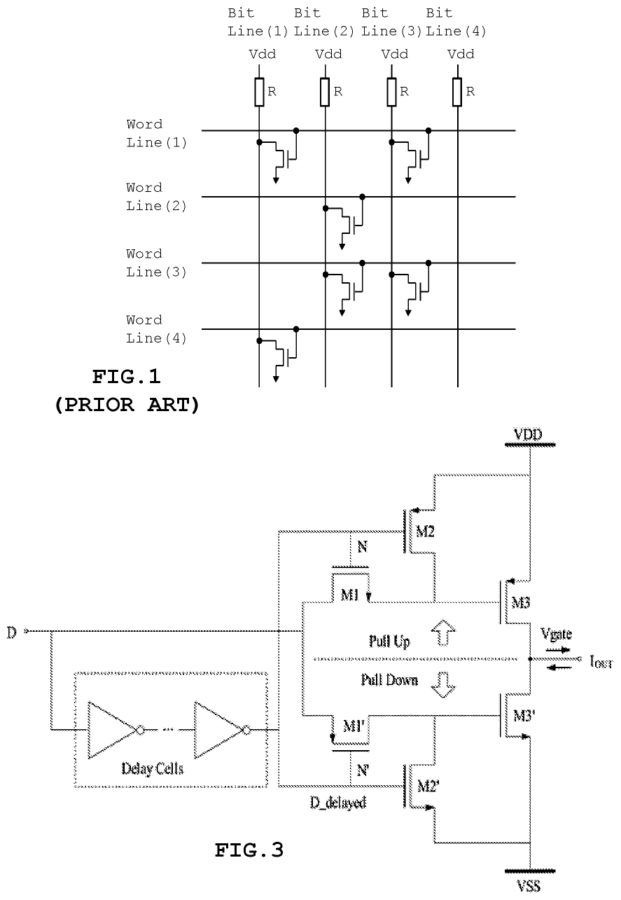

FIG. 1 is a circuit diagram for an example of a typical mask ROM core. The ROM memory core comprises a grid of word lines (the address input) and bit lines (the data output) perpendicular to the word lines. A transistor switch is connected between the intersecting word line and bit line at selected intersections. The mask ROM represents an arbitrary look-up table with a regular physical layout and predictable propagation delay. Each intersection of word line and bit line forms a memory cell storing one bit, for example having a transistor connected to produce a binary “0” or having no transistor connected to produce a binary “1”. In the example shown in FIG. 1, an NMOS transistor with grounded source terminal is formed at selected intersections of the matrix, and a pull-up resistor is connected to every bit line. When one of the address-decoded word lines is driven with a “1”, the bit lines having a transistor connected to the word line will be pulled down by the transistor to generate a “0 ” output, and the bit lines without a transistor connected will be pulled up by the bit-line pull-up resistor to generate a “1” output.

The conventional mask ROM is thus programmed with the desired code during front-end processing of the chip, usually using a conventional mask-based lithography process. This is feasible when large numbers of the ROM are to be produced all storing the same code, e.g. software code for a microcontroller. However, this process is impractical when it is desired that each ROM stores a different code and that the code for each ROM can be more flexibly allocated after front-end processing of the chip. Furthermore, it is desirable that the ROM should be possible in both MOS and bipolar technology.

Also, no helpful documents are in fact found in case specific designs are looked for that could support a design towards the aim of the present invention, viz. an integrated circuit having an IC-specific code which is hard-coded into the structure of the integrated circuit, In this respect, for instance US patent publications 2007141865A1 and 2008121709 may seem somewhat relate somewhat to the above matter, however do not provide any solution or incentive to the present aim and problem. In exemplifying such, if it might be be concluded that the latter publication discloses a hard coding in an upper layer, a problem to be solved could be regarded as the provision of an alternative design for a hard-codeable electrically readable N-bit binary code. An object of the present invention remains the provision of a generic IC design that allows a subsequent preferably unique hard coding thereof in an indicated, i.e. electronically readable manner.

### SUMMARY OF THE INVENTION

The present invention overcomes the limitations of the prior art by providing an integrated circuit with a predetermined IC-specific code permanently hard-coded into the integrated circuit.

According to an aspect of the invention, an integrated circuit is provided having a predetermined IC-specific N-bit binary code hard-coded into the structure of the integrated circuit. The integrated circuit comprises a plurality of logic voltage lines; N identical bit circuits, each adapted to generate one bit of the N-bit code, the bit circuits being formed in a plurality of first lower layers of the integrated circuit, wherein each bit circuit comprises an input and an output; N identical pull-down circuits, each electrically connecting an input of one of the N bit circuits to one of the logic voltage lines, the pull-down circuits being formed in the first lower layers of the integrated circuit; and a plurality of programmable conductive connections formed above the first lower layers, the programmable conductive connections electrically connecting an input of a selected set of the bit circuits to one of the logic voltage lines. For the inputs of the selected set of the bit circuits, the logic voltage line electrically connected via the respective pull-down circuit and the logic voltage line electrically connected via the respective programmable conductive connection, represent different logic levels, wherein the electrical connections via the programmable conductive connections in conjunction with the bit circuits and the pull-down circuits, hard-code the IC-specific N-bit binary code into the integrated circuit.

In such a design, the inputs of all of the bit circuits are electrically connected to a logic voltage line via one of the pull-down circuits. A selected set of bit circuits have an input which is also electrically connected to another logic voltage line. In this way, the voltage at the input of the selected bit circuits is pulled towards the voltage of the logic voltage line which is electrically connected via a respective programmable conductive connection. The voltage at the input of the other (non-selected) bit circuits is pulled towards the voltage of the logic voltage line which is electrically connected via a respective pull-down circuit. In this way, the programmable conductive connections are used to hard-code the IC-specific N-bit binary code into the integrated circuit, e.g. an IC having M bit circuits in the selected set stores a binary code comprising M logic one bits and N-M logic zero bits, or M logic zero bits and N-M logic one bits.

Moreover, as to advantages of such a novel set-up as in particular for a secure device, the method of encoding does not need any electronic support other than the sole act of etching for programming the circuit. Rather, in accordance with the aim of the invention the present method of realizing secure trust anchors renders an immutable, unique circuit. It cannot be influenced or changed in any way electronically from the integrated circuit after encoding. This newly proposed device and process of manufacturing therefor is used in process, i.e. in mid end, before the circuit has been switched on. It may be understood that it is within this context that, if applied, any on wafer test is or could be performed. The new method and device moreover ensure that it is impossible to make any corrections to any device produced according to this process, e.g. after proven problems with an NVM.

The inclusion of a separate layer of programmable connections facilitates easy use of the low energy intensity process of etching, i.e. when compare to high energy intense processes such as laser blowing of electronic fuses, of which also the difference in physical effect on the electronic devices structures can be clearly distinguished when using the thereto available appropriate tooling in this technical field. Having the layer of programmable connections included physically above the first layers constituting the generic or common part of the specified electronic circuit of the new device, allows for ease of in fact mechanical access of the programmable connections, such as required at etching. The programming step by way of etching as here defined for the purpose of realizing a secure, trusted device or element not only ensures that the encoding can be performed in a separate, controlled environment as compared to a generic foundry in which the lower layers of the device may be produced, but in fact enable the producer and seller of the device to guarantee the immutable, secure nature of the device, so that it can be used as a trust anchor in security systems, the device being of a nature that can not easily be tampered with. Incidentally, if tampered with, device merely reveals a single ID value, strongly discouraging attempts towards hacking such a new device.

This structure enables the integrated circuit to be manufactured with a predetermined hard-coded IC-specific code, using a minimum number of processing steps which are specific (individualized) to the IC. The identical bit circuits and pull-down circuits formed on the lower layers of the IC may be manufactured using a conventional front-end process using mask-based lithography, a well-established and highly developed manufacturing process which is best suited for manufacturing large quantities of ICs having identical circuits, at low-cost and high yield. By using a mask-based process to form the identical parts of the ICs, the high cost of the masks is amortised over a large number of ICs which can be produced from a set of masks.

In contrast, the hard-coding of the IC-specific code can be accomplished using a maskless lithography process to make or break selected ones of the programmable conductive connections, which are formed at a higher layer of the IC where the minimum feature size is larger than for the lower layers where the bit circuits are formed. Since the IC-specific code will be different for different ones of the ICs on a wafer and preferably different for different wafers, the cost of masks cannot be amortised over a large number of ICs. This makes it prohibitively expensive to use mask-based lithography for the hard-coding. Instead, maskless lithography is used and this is made feasible by the design of the ICs, having a limited number of larger dimension areas which need to be exposed to “program” the programmable conductive connections. For example, a maskless electron beam exposure tool may be used having a single beam or shaped beam, or an optical maskless exposure tool using a scanning modulated laser beam or micro-mirror modulated light beam.

Using the programmable conductive connections, the portion of the structure of the ICs which needs to be individualized, and the manufacturing steps to accomplish the individualization, are reduced to a minimum, so that high-volume low-cost conventional techniques can be used for making a maximal amount of the structure of the ICs and used for a maximal number of the manufacturing steps. Under these conditions is becomes practical to use maskless lithography for the minimal structure which is individualized per chip. Although maskless lithography tools have lower throughput compared to mask-based lithography, their use becomes feasible due to the limited steps they need to perform for making the programmable conductive connections.

It is furthermore remarked that earlier mentioned disclosure US2008121709 falls short in disclosing or even incenting the presently claimed invention in that at least it does not mention N identical pull down circuits that each connect an input of one of the N bit-circuits with a logical connection in which the pull down circuits are formed in the first lower layers of the integrated circuits. The publication neither discloses the features as specified by the characterizing portion of the present claim, in that it does not disclose for the inputs of the selected set of the bit circuits, the logic voltage line electrically connected via the respective pull-down circuit and the logic voltage line electrically connected via the respective programmable conductive connection, represent different logic levels. Nor does it disclose that the electrical connections via the programmable conductive connections in conjunction with the bit circuits and the pull-down circuits, hard-code the IC-specific N-bit binary code into the integrated circuit. Hence none of the prior art suggests to connect all of the N identical bits circuits as might be identified therein, via a pull down circuit to a logical voltage line indicating a different logical level. Moreover, the latter discussed prior art document teaches to use a single conductive layer to connect either to VSS or VDD, implying that there neither is disclosed a teaching to use a further layer differing from this single conductive layer to provide one of the connections to VSS or VDD. Also in US2007141865, while showing a bit circuit version identification with an input connected to one of two pull up/pull down circuits, there is no suggestion to connect the input to both circuits. This document is silent to the location of the programmable conductive connections with respect to the bit circuits, hence neither suggests the claimed subject matter, not motivates a skilled person to modify the circuit of e.g. US2008121709 in order to arrive at the claimed subject matter.

In an embodiment, each one of the bit circuits has a programmable conductive connection electrically connected to the input of that bit circuit, wherein selected ones of the programmable conductive connections have been altered to break the electrical connection between the input of the respective bit circuit and the respective logic voltage line. In this way, a complete set of identical programmable conductive connections can be formed initially, each electrically connecting the input of a corresponding bit circuit to one of the logic voltage lines. For example, this may form an IC storing a binary code of all ones or all zeros. Then selected ones of the programmable conductive connections are altered to break the electrical connection between the bit circuit input and the logic voltage line. This reduces the number of processing steps which need to be individualized for the IC for hard-coding of the IC-specific code, only requiring altering the selected programmable conductive connections.

In an embodiment, the altered programmable conductive connections have a portion removed by selectively etching the programmable conductive connections to break the electrical connection between the input of the respective bit circuit and the respective logic voltage line. In this way, the N-bit binary code can be hard-coded into the integrated circuit simply by etching selected ones of the programmable conductive connections. This enables the individualized processing step for the IC to be reduced to a minimum, for example only requiring an exposure step specific to the IC for exposing the parts of the programmable conductive connections to be selectively etched. This minimal exposure step, performed at a higher layer of the IC where the dimensions are larger, enables the use of maskless lithography.

In an embodiment, during operation the electrical connections formed by unaltered programmable conductive connections operate to pull the input of the respective bit circuit towards the voltage of the respective logic voltage line. In this way, during operation when voltage is applied to the IC, the input of the bit circuit will be pulled towards the voltage of the respective logic voltage line by the respective (unaltered) programmable electrical connection. As a result, during operation, the inputs of the bit circuits will either be pulled towards the voltage of one logic voltage line by the respective pull-down circuit (if the respective programmable conductive connection has been altered to break the electrical interconnection), or pulled towards the voltage of another logic voltage line by the respective programmable conductive connection (if it has not been altered). In this way, the N-bit binary code is hard-coded into the integrated circuit, so that the bit circuits generate the code at their outputs.

In an embodiment, the selected set of bit circuits have one of the programmable conductive connections formed in a contact hole to electrically connect the input of the respective selected bit circuit and the respective logic voltage line, while the remaining bit circuits do not have a programmable conductive connections formed in a contact hole. In this variation, not all of the bit circuits have a corresponding programmable conductive connection. Only selected ones of the bit circuits have a corresponding programmable conductive connection, and these connections are formed via a contact hole. Thus, as opposed to forming a programmable conductive connection for each bit circuit and altering (removing) selected ones, only the selected programmable conductive connections are formed and no altering is needed. This again enables the individualized processing step for the IC to be reduced to a minimum, for example only requiring an exposure step specific to the IC for exposing the areas where a contact is to be formed for a programmable conductive connection.

In an embodiment, during operation, the programmable conductive connections operate to pull the input of the respective bit circuit towards the respective logic voltage line. As a result, during operation of the IC, the inputs of the bit circuits will either be pulled towards the voltage of one of the logic voltage lines by the respective pull-down circuit (if there is no programmable conductive connection formed for that bit circuit), or pulled towards the voltage of a different logic voltage line by the respective programmable conductive connection. In this way, the N-bit binary code is hard-coded into the integrated circuit, so that the bit circuits generate the code at their outputs.

In an embodiment, each of the bit circuits is adapted to transfer the binary state at its input (either high or low voltage) to its output. The bit circuits may each comprise at least one buffer circuit, e.g. a non-inverting buffer or an inverting buffer. The bit circuits may each implement a memory cell of a ROM, for example each storing one bit of the N-bit binary code.

In an embodiment, the pull-down circuits each provide a soft pull-down of the voltage at the input of the respective bit circuit towards the voltage of the first logic voltage line. This prevents that the input of any of the bit circuits floats. This soft pull-down can be overridden by a stronger pull-up provided by a respective programmable conductive connection connected to the input of the respective bit circuit, if a programmable conductive connection has been formed for the bit circuit and has not been altered to break the electrical connection to a logic voltage line. Note that the voltage of the logic voltage line connected via a pull-down circuit may be higher or lower than the voltage of the logic voltage line connected via a programmable conductive connection, and thus the phrase “pull-down” as used herein should be understood to refer to pulling voltage up or down depending on the configuration of the IC, e.g. increasing or reducing the voltage at the input of the relevant bit circuit.

In an embodiment, a passivation layer is formed over the plurality of first lower layers, wherein the programmable conductive connections are formed above the passivation layer, the programmable conductive connections being electrically connected to the respective bit circuits via contact holes in the passivation layer. This protects the circuits and structures comprising the bit circuits formed in the lower layers, which may be advantageously formed in a front-end process using a conventional mask-based lithography process, while the wafer is transferred for further processing to form the programmable conductive connections which implement the IC-specific code in the IC.

In an embodiment, the programmable conductive connections are formed in a single layer, and the single layer may be above the passivation layer. Forming the programmable conductive connections in a single layer reduces the number and simplifies the individualized processing steps needed for hard-coding the IC-specific code, for example only requiring an exposure step specific to the IC for one layer of the IC.

In an embodiment, the integrated circuit further comprises one or more bond pads electrically connectable to the output of the bit circuits, wherein the IC-specific N-bit binary code is readable from the one or more bond pads.

In an embodiment, the selected set of bit circuits comprises fewer than N bit circuits.

According to another aspect of the invention, a method is provided for hard-coding a predetermined IC-specific N-bit binary code into the structure of an integrated circuit. The method comprises providing an integrated circuit having: a plurality of logic voltage lines; N identical bit circuits, each adapted to generate one bit of the N-bit code, the bit circuits being formed in a plurality of first lower layers of the integrated circuit, wherein each bit circuit comprises an input and an output; and N identical pull-down circuits, each electrically connecting an input of one of the N bit circuits to one of the logic voltage lines, the pull-down circuits being formed in the first lower layers of the integrated circuit. In a first alternative, the method comprises the further steps of forming N programmable conductive connections above the first lower layers, each electrically connecting an input of one of the bit circuits to one of the logic voltage lines, and altering selected ones of the programmable conductive connections to break the electrical connection between the input of the respective bit circuit and the respective logic voltage line. In a second alternative, the method instead comprises the further step of forming a plurality of programmable conductive connections above the first lower layers, the programmable conductive connections electrically connecting the input of a selected set of the bit circuits to one of the logic voltage lines, wherein the remaining bit circuits do not have a programmable conductive connection. For both alternatives, the inputs of the selected set of the bit circuits, the logic voltage line electrically connected via the respective pull-down circuit and the logic voltage line electrically connected via the respective programmable conductive connection, represent different logic levels. The electrical connections via the programmable conductive connections in conjunction with the bit circuits and the pull-down circuits, hard-code the IC-specific N-bit binary code into the integrated circuit.

In an embodiment, the step (of the first alternative) of altering selected ones of the programmable conductive connections comprises removing a portion of the selected programmable conductive connections by selective etching to break the electrical connection between the input of the respective bit circuit and the respective logic voltage line.

In an embodiment, the step (of the second alternative) of forming the plurality of programmable conductive connections electrically connecting to an input of one of a selected set of the bit circuits comprises forming the programmable conductive connections in a contact hole.

Thus, the integrated circuit comprises a set of identical bit circuits which generate the bits of the IC-specific N-bit binary code, the values of the bits determined by the programmable conductive connections. In this way, the IC has the IC-specific code hard-coded into the IC. The IC circuit is unusual in that it includes more circuits than necessary to store the code, i.e. every bit circuit has a pull-down circuit, including the selected bit circuits which have an associated programmable conductive connection to pull the voltage of the input of the bit circuit in the opposite direction to the pull-down circuit. However, this construction enables identical bit circuits (including the pull-down circuits) to be manufactured using a conventional mask-based lithography process, while the programmable conductive connections which are individualized for the IC by adding or breaking individual programmable conductive connections, are manufactured using a maskless lithography process. This is feasible since only minimal steps are required to individualize the programmable conductive connections, which are formed at an upper layer of the IC where the minimum dimensions are larger.

Aspects and embodiments of the invention are further described in the following description and in the claims.

Embodiments will now be described, by way of example only, with reference to the accompanying schematic drawings in which corresponding reference symbols indicate corresponding parts, and in which:

FIG. 1 is a simplified schematic circuit diagram for a conventional mask ROM core;

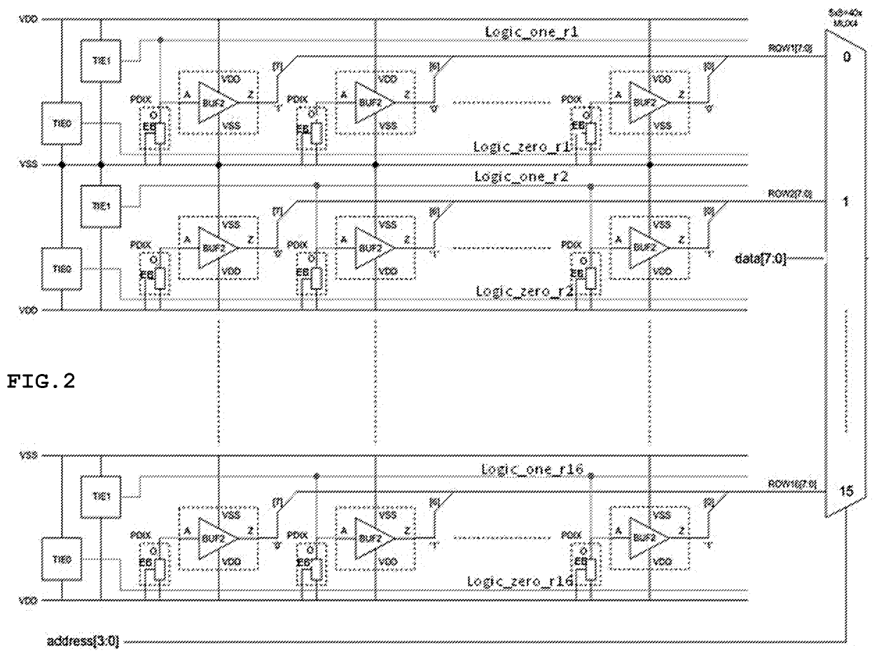

FIG. 2 is a simplified schematic circuit diagram of an embodiment of an integrated circuit having a predetermined IC-specific N-bit binary code hard-coded into the structure of the IC;

FIG. 3 is a simplified schematic circuit diagram of an embodiment of a pull-down circuit for use the integrated circuit of FIG. 2;

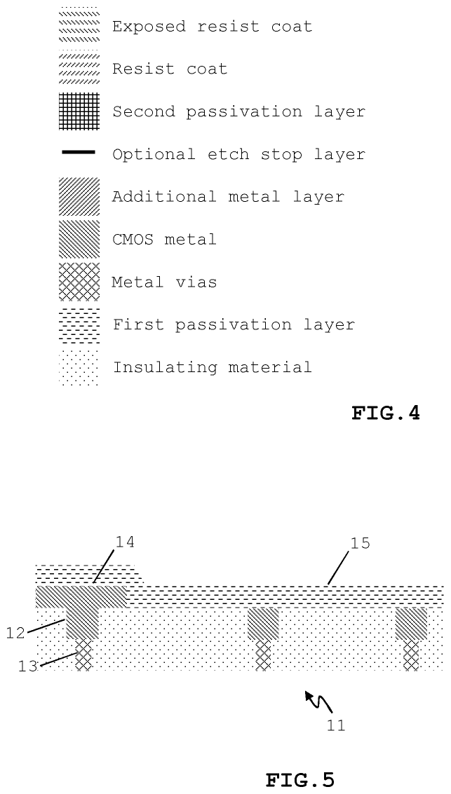

FIG. 4 shows a legend for FIGS. 5-8;

FIGS. 5 to 7 show an example of manufacturing steps for manufacturing the integrated circuit of FIG. 2;

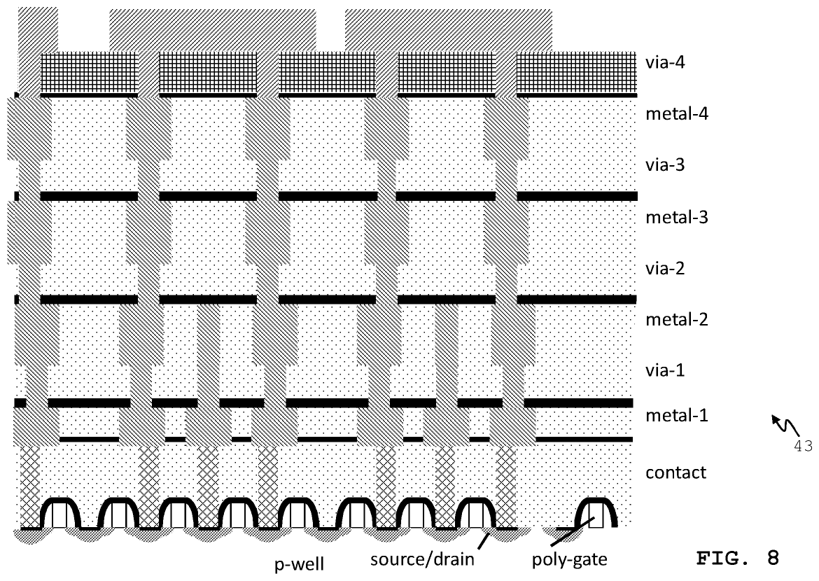

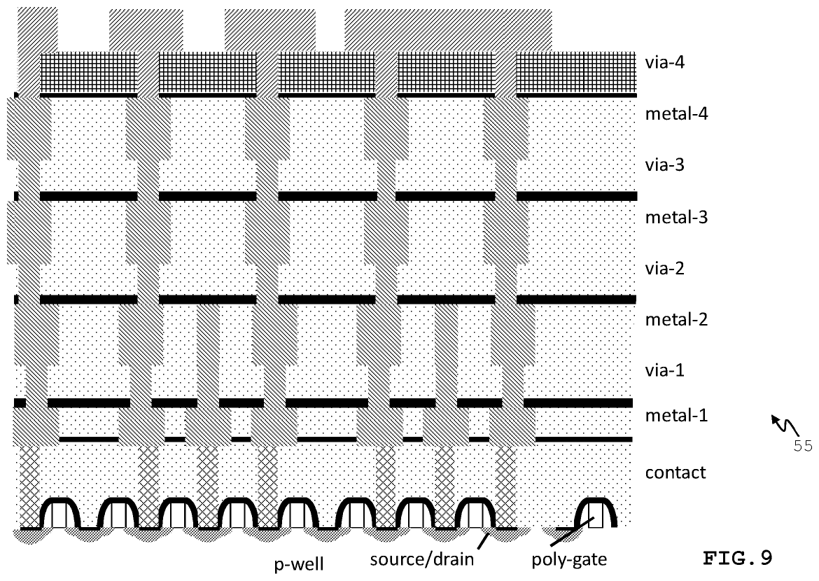

FIGS. 8 and 9 show further examples of manufacturing steps for manufacturing the integrated circuit of FIG. 2;

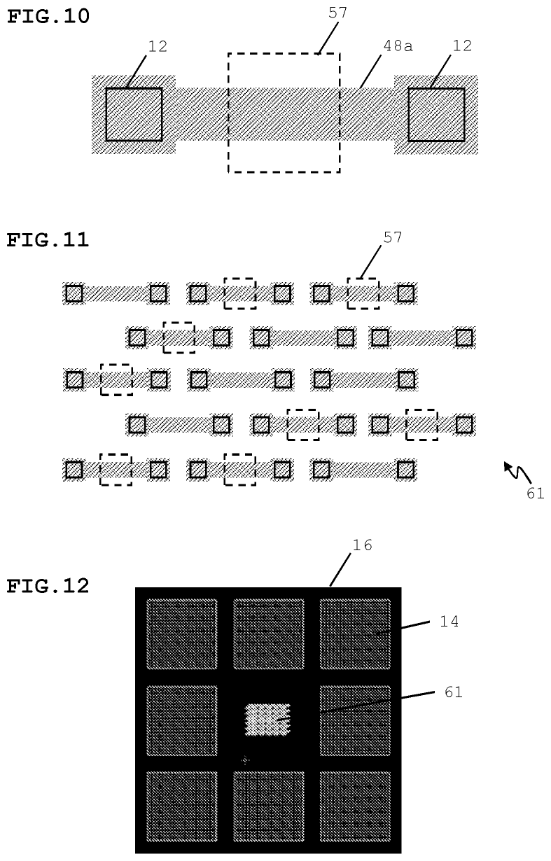

FIGS. 10 to 12 show examples of an arrangement of programmable conductive connections on the integrated circuit of FIG. 2;

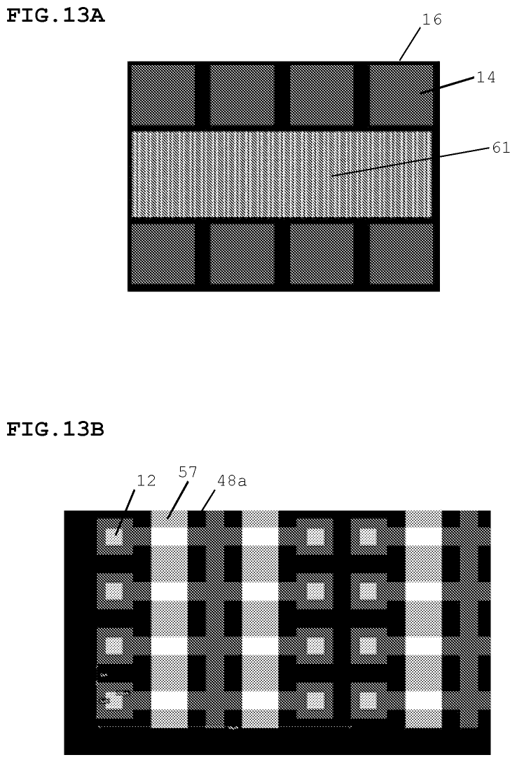

FIGS. 13A and 13B show another example of an arrangement of programmable conductive connections on the integrated circuit of FIG. 2; and

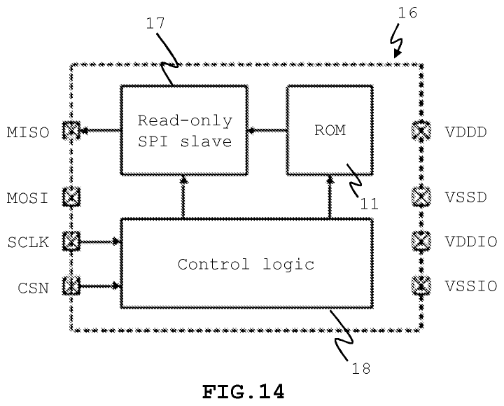

FIG. 14 is a schematic diagram of an embodiment of a complete chips including the integrated circuit of FIG. 2.

The figures are intended for illustrative purposes only, and do not serve as restriction of the scope or the protection as laid down by the claims.

FIG. 2 is a schematic diagram of an embodiment of an integrated circuit having a predetermined IC-specific N-bit binary code hard-coded into the structure of the IC. The IC comprises a plurality of logic voltage lines, the lines carrying a relatively low voltage (e.g. which may represent a logical “0”) or a relatively high voltage (e.g. which may represent a logical “1”). The logic voltage lines may be connected to the power supply voltages supplied to or generated in the IC, for example Vss for a MOS circuit (or V_{EE} for a bipolar circuit) being the low logic voltage (e.g. common or ground voltage) and Vdd (or V_{CC}) being the high logic voltage(e.g. +5V). For example, the power supply lines may be used as the logic voltage lines. In addition to (or instead of) this arrangement, logic voltage lines may be generated from the power supply voltages, for example a low logic voltage line TIE0 and a high logic voltage line TIE1 as shown in the embodiment of FIG. 2. This arrangement enables circuitry to be added to avoid ripple in the power supply voltages Vdd, Vss from propagating to these logic voltage lines TIE1, TIE0. Note that this arrangement with logic voltage lines TIE1 and TIE0 is preferred, but these lines can be omitted and only power supply lines Vdd, Vss used for the logic voltage lines.

The IC comprises a plurality of identical bit circuits BUF2. For an IC designed to store an N-bit binary code, the IC may include N bit circuits, each adapted to generate one bit of the N-bit code. Each bit circuit BUF2 is adapted to transfer the binary state at the input (i.e. either a high or low voltage) to the output of the bit circuit. The bit circuits BUF2 may each comprise at least one buffer circuit, e.g. a non-inverting buffer or an inverting buffer, used to establish a stable output at a logical low level (i.e. a logical “0”) or a logical high level (i.e. a logical “1”). Alternative circuits may also be used, such as an op-amp or logic gate or simple circuit with only passive component(s).

The bit circuits BUF2 may each function as a memory cell of a ROM, in which each bit circuit generates one bit of the N-bit binary code stored in the IC, and the bit circuits can be created in bipolar or MOS technology. In the embodiment shown in FIG. 2, there are 16 rows of bit circuits BUF 2, each row including 8 bit circuits, providing a capacity to store sixteen 8-bit bytes of binary data. Other numbers and arrangements of bit circuits are of course possible for storing different amounts of data.

The IC also comprises a plurality of pull-down circuits PDIX. One pull-down circuit PDIX is provided for each bit circuit BUF2, and each pull-down circuit PDIX electrically connects the input of one of the bit circuits BUF2 to one of the logic voltage lines. FIG. 3 shows an example of a pull-down circuit PDIX which may be used in the IC of FIG. 2, although many other circuit designs are possible, including active components or solely passive components.

In the embodiment shown in FIG. 2, the pull-down circuits PDIX connect the inputs of all bit circuits BUF2 in the first row to Vss, and connect the inputs of all bit circuits BUF2 in the second row to Vdd. The pull-down circuits PDIX preferably each provide a “soft” pull-down of the voltage at the input of the respective bit circuit BUF2 towards the voltage of the relevant logic voltage line, to prevent the input of the bit circuit from floating.

The IC also includes a plurality of programmable conductive connections. For a selected set of the bit circuits BUF2, a programmable conductive connection is used to electrically connect the input of a bit circuit BUF2 to a different one of the logic voltage lines TIE0, TIE1, Vdd, Vss than is electrically connected via the respective pull-down circuit PDIX. For example, in the embodiment shown in FIG. 2, the inputs of all bit circuits BUF2 in the first row are connected to logic voltage line Vss via the pull-down circuits PDIX, and the inputs of selected ones of the bit circuits BUF2 are connected to logic voltage line TIE1 via one of the programmable conductive connections. In this example, the logic voltage line TIE1 represents a logic “1”, and the logic voltage line Vss represents a logic “0”. In the second row, the bit circuit inputs BUF2 are connected to logic voltage line Vdd via the pull-down circuits PDIX, which represents a logic “0” for these bit circuits. Note that the pull-down circuits may be all connected to the same logic voltage line, or to different logic voltage lines which all represent the same logic value, or to different logic voltage lines which represent different logic values. However, for each of the selected bit circuits, the pull-down circuit and the programmable conductive connection electrically connect to logic voltage lines representing different logic values.

The programmable conductive connections may be formed as needed for selected bit circuits, or they may be formed for all bit circuits and then selected ones altered to break the electrical connection created by the programmable conductive connection for selected bit circuits. This altering can be achieved by selective etching to remove a portion of the selected programmable conductive connections, or otherwise cutting or breaking the programmable conductive connections, e.g. using lasers, e-beams or by mechanical means.

The pull-down circuits PDIX provide a soft pull-down that can be overridden by a stronger pull-up provided by a respective programmable conductive connection (if one has been formed for the bit circuit and has not been altered to break the electrical connection). Note that the phrase “pull-down” can refer to pulling a voltage up or down, depending on the configuration of the IC. The IC can be configured in many different configurations using this design.

In a first example, the input of all of the bit circuits are electrically connected via a respective pull-down circuit to a logic voltage line having a voltage representing a logical “0”. The input of all of the bit circuits are also electrically connected via a respective programmable conductive connection to a logic voltage line having a voltage representing a logical “1”, and selected ones of the programmable conductive connections for selected bit circuits are etched to break this electrical connection. As a result, the selected bit circuits output a logical “0” (due to the pull-down circuits) and the remaining bit circuits output a logical “1” (due to the unbroken programmable conductive connections).

In a second example, the input of all of the bit circuits are electrically connected via a respective pull-down circuit to a logic voltage line having a voltage representing a logical “0”. The input of selected bit circuits are electrically connected via a respective pull-down circuit to a logic voltage line having a voltage representing a logical “1”. As a result, the selected bit circuits output a logical “1” (due to the programmable conductive connections) and the remaining bit circuits output a logical “0” (due to the pull-down circuits).

These two examples may also be configured with the logical “1” and logical “0” reversed. Thus, the programmable conductive connections, in conjunction with the bit circuits and the pull-down circuits, function to hard-code the IC-specific N-bit binary code into the integrated circuit.

The bit circuits BUF2 and the pull-down circuits PDIX are formed in a plurality of first lower layers of the integrated circuit, while the programmable conductive connections are formed above the first lower layers. The programmable conductive connections are thus formed at an upper layer of the stack of layers forming the IC. They may be formed at the highest metal layer, e.g. as shown in the examples of FIGS. 4 to 9, in a Re-Distribution Layer (RDL) or routing layer.

The design of the IC preferably has the same electrical performance as a conventional ROM, but has a different circuit structure and different means of programming the binary code.

A method for making the integrated circuit is described with respect to FIGS. 4-9.

FIG. 4 shows a legend for FIGS. 5-9, indicating different materials that may be used in the layers forming the IC. As will be further explained in the examples of FIGS. 5-9, the insulating material, passivation material, through passivation contacts and CMOS metal are typically created in a conventional front-end fabrication process. The routing metal, protection material and resist coat may be applied in a front-end processing or a mid-end processing.

FIG. 5 is a schematic diagram showing a cross-section through a wafer. A large number of ICs have been formed on the wafer using a conventional front-end process, the ICs having identical circuits including the bit circuits and pull-down circuits, being made using conventional mask-based lithography, preferably a CMOS process. FIG. 5 shows the wafer with IC 11 after completion of the conventional front-end process, before transferring the wafer to the manufacturing facility to perform the mid-end process. Only the upper layers of IC 11 are shown, including a metal routing layer 12 connected by metal vias or contacts 13 through one or more insulating layers to portions of the circuit of IC 11 formed on lower layers on the wafer. Bond pads 14, for connecting IC 11 to external components, are connected to the routing layer 12.

A passivation layer 15 is formed over the top of the wafer to seal and protect the underlying layers, and render the wafer with IC 11 inert, to avoid undesired interaction with air, moisture or other materials that may come into contact with the surface of the wafer. The passivation layer 15 may optionally be removed from a portion of the bond pads 14, as part of the conventional front-end process.

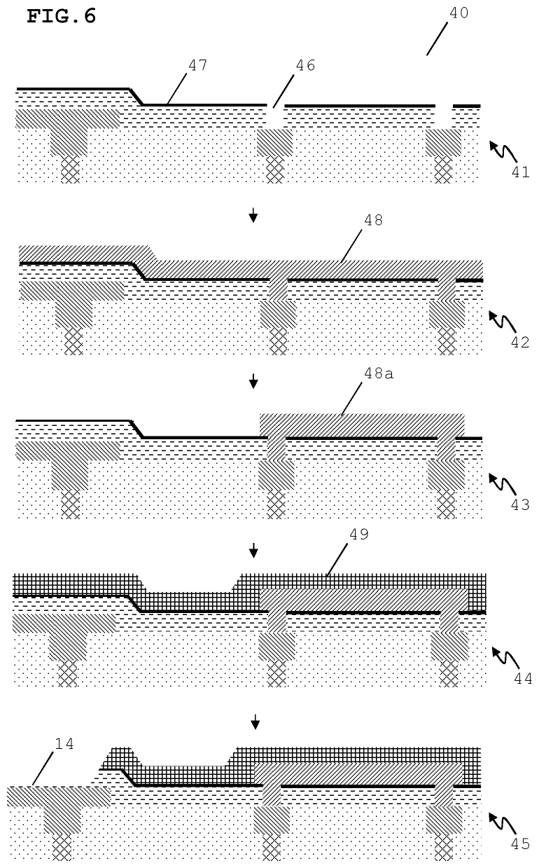

FIG. 6 shows an example of steps 41-45 that may be performed in a first phase 40 of the manufacturing process to form the programmable conductive connections. The manufacturing process illustrated in FIGS. 6 to 9 is for forming programmable conductive connections for every bit circuit, and then altering (etching) selected programmable conductive connections to program the IC with the predetermined IC-specific code. Those skilled in the art will appreciate that a similar process can be employed for an alternative embodiment in which only selected programmable conductive connections are formed in contact holes (e.g. where the exposed target areas are located in the positions where contact holes are to be formed, which are then filled to create programmable conductive connections).

In step 41, contact holes 46 are etched through the passivation layer 15 above portions of the metal layer 12. As show in step 41, an optional etch stop layer 47 may be formed on the passivation layer before etching. In step 42, metal deposition is performed, resulting in an additional metal layer 48 (or other conducting material such as polysilicon) being deposited on top of the passivation layer 15 and making contact with portions of the routing metal layer 12 of the IC created in the front-end process. This may be accomplished by forming conductive plugs (e.g. of Tungsten) in the contact holes 46 and subsequently forming the additional metal layer 48 over the top. In step 43, patterning of the additional metal layer 48 is performed, resulting in selected parts of the metal layer 48 being removed. The remaining portions of the metal layer 48 form the programmable conductive connections 48a.

Steps 41 to 43 are preferably performed using conventional mask-based lithography, and preferably using the same materials and processes as used in the front-end processing used for the lower layers. In some embodiments, the layout of the programmable conductive connections 48a is identical for every IC on the wafer, so that it is possible (and has advantages) to use conventional mask-based lithography tools and processes to reduce the cost of the mid-end processing.

An example of the result of a step 43 is shown in FIG. 8, wherein a patterned additional metal layer 48 is shown as the top metal/conductive layer (note that FIG. 8 and FIG. 6 show different metal layer designs). In FIG. 8, the patterned (top) additional layer and the vias in the via-4 layer created in the mid-end process are connected to the layers below the via-4 layer including the CMOS elements (p-well, source/drain and poly-gate) forming the transistors of a ROM. In the example of FIG. 8, the additional metal layer is connected to the CMOS elements through a number of metal layers metal-1, metal-2, metal-3 and metal-4, a number of vias in via layers via-1, via-2, via-3 and via-4, and a number of contacts in the contact layer.

In step 44, an additional protection (passivation) layer 49 may be added. In step 45, the passivation layers 15 and 49 (and etch stop layer 47 if present) are removed from a portion of the bond pads 14 to permit a subsequent wire bonding operation during back-end processing.

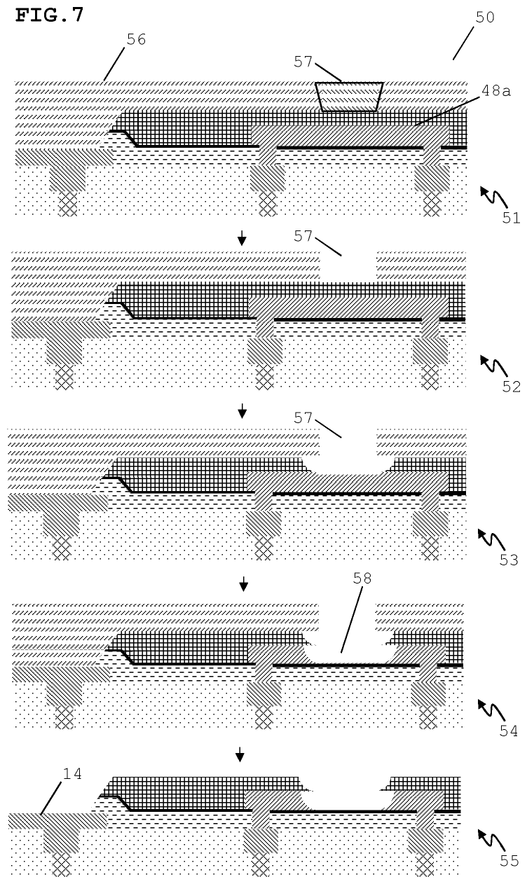

FIG. 7 shows an example of steps 51-55 that may be performed in a second phase 50 of the manufacturing process to form the programmable conductive connections. In step 51, a coating of resist 56 is applied to the surface of the wafer and exposed in certain target portions 57, each target portion 57 comprising a small area overlying a portion of a corresponding programmable conductive connection 48a. The exposure of the target portions 57 is performed by a maskless lithography process. Conventional mask-based lithography is not suited for this step, since the set of target portions 57 to be exposed for each IC is different for different ICs on the wafer, and may be unique for every IC on the wafer. Since a conventional mask provides the pattern for only a small area of the wafer, and a conventional mask-based lithography tool repeatedly uses the same mask to progressively expose each area of the wafer, it is not feasible to use a mask to expose the target portions 57. Instead, a maskless lithography tool is preferably used to expose the selected set of target portions 57 for each IC 11.

In step 52, the resist is developed and removed from the exposed target areas, and in step 53 the passivation layer 49 is selectively etched in the target areas 57, resulting in portions of certain selected ones of the interconnections 48a under the exposed set of target areas 57 being uncovered.

In step 54, the uncovered portions of the programmable conductive connections 48a are etched (typically using a conventional etching process) to remove the metal 58 of the selected interconnections 48a under the target areas 57. This results in breaking the interconnection formed between the circuit portions of the IC 11 which had been made by each of the selected programmable conductive connections 48a. In step 55, the resist is stripped and the top layer may be cleaned. The wafer is subsequently cut into pieces (diced) to separate each IC which then undergoes bank-end processing.

An example of the result of a step 55 is shown in FIG. 9, which is similar to FIG. 8 except for the top layer wherein the patterned additional metal layer has been altered by breaking connections resulting in an IC-specific code being hard-coded into the ROM of the integrated circuit (note that FIG. 9 and FIG. 7 show different metal layer designs).

FIG. 10 is a schematic diagram showing a plan view of a single programmable conductive connection 48a. The programmable conductive connections 48a are formed in the shape of an elongated line of conductive material (e.g. metal), arranged between two portions of the underlying metal routing layer 12 to which the programmable conductive connection 48a is connected. A target portion 57 is located over a central part of the programmable conductive connection 48a, and is slightly wider than the width of the elongated line. For example, the elongated line may be 4 microns in length and 1 micron in width, with a target portion 3 microns wide and 2 microns long over the central portion of the elongated line.

FIG. 11 is a schematic diagram showing a plan view of a portion of an array 61 of programmable conductive connections 48a and corresponding selected target portions 57.

The programmable conductive connections 48a are arranged in a regular array with the same distance separating the central part of each connection 48a (where a target portion 57 may be located) from adjacent central parts in x and y directions. For example, the array 61 may comprise 128 programmable conductive connections 48a and 128 target portions 57, for storing a 128-bit binary code in the IC. Larger or smaller arrays 61 may be implemented, depending on the size of the code to be programmed into the IC.

FIG. 12 is a schematic diagram showing a plan view of a complete chip 16 which comprises the IC 11, showing an example of an arrangement of bond pads 14 and an array 61 of programmable conductive connections 48a and target portions 57. The IC-specific code hard-coded into the chip 16 may be accessed by external components by reading the code via the bond pads 14. For example, a standardized serial peripheral interface (SPI) may be implemented in the chip 16 and used to read the IC-specific code from the chip 16.

FIG. 13A is a schematic diagram showing a plan view of another example of a complete chip 16 having the same general structure as described above, but having a different arrangement of bond pads 14 and of the programmable conductive connections 48a and target portions 57 in the array 61. FIG. 13B is an enlarged plan view of a portion of the array 61 of programmable conductive connections 48a and corresponding selected target portions 57. In this example, the central parts of each programmable conductive connection 48a (where the target portions 57 may be located) are aligned in columns, so that the target portions 57 are aligned in multiple columns. Each column of target portions can be exposed by scanning a light beam or electron beam along the column and modulating the beam to selectively expose selected ones of the target portions 57. The horizontally-aligned programmable conductive connections 48a may be arranged with equal spacing between them in each column, to further simplify control of the exposure beam modulation. For example, each programmable conductive connection 48a in this arrangement may have one end electrically connected a common voltage line (e.g. a 3V or 0V line) and the other end electrically connected to a separate logic circuit or memory cell, to implement a modified circuit that stores a binary code.

FIG. 14 shows a schematic diagram of an exemplary complete packaged chip 16 including an IC 11 storing an IC-specific code as described herein. The chip 16 may include further parts that have been created in the front-end processing. The chip 16 may include an interface, here embodied in the form of a Serial Peripheral Interface (SPI) 17 and control logic 18 for outputting the identifier on a request received via the Control logic. The chip 16 may include voltage inputs VDDD, VSSD, VDDIO and VSSIO. The chip 16 may further include signal inputs MOSI (Master Output Slave Input), SCLK (Serial CloCK) and CSN (Chip Select Not). The chip 16 may further include signal output MISO (Master Input Slave Output). It will be understood that the IC is not limited to having SPI-based interfaces. Other non-limiting examples of interfaces that may be used are serial interfaces such as I2C or I2S, 3-wire, 1-wire , USB or a classical 13,56 MHz RF-ID contactless interface.

The chip 16 may be a miniature SO8-packaged IC e.g. for board-level applications. Any other suitable packaging may be used, e.g. SSOP 8, TSSOP 8, 8WLCSP, or various leadless packages. The chip 16 may include a RF-ID compatible IC, which may be used for object authentication. The chip 16 may be integrated in a multi-chip package. The chip may be integrated as IP block in a larger IC.

The hardware of the chip 16 is preferably made as simple and cheap as possible.

The chip 16 may be dedicated to the function of storing the hard-coded IC-specific code, i.e. the function provided by chip 16 may be limited to outputting the IC-specific code upon request. This design enables production of the IC 11 and chip 16 which is as simple and cheap as possible.

Thus, the invention as described herein enables production of small low-cost integrated circuits which have an IC-specific code permanently stored in the structure of the integrated circuit. The scope of the invention is not limited to the embodiments and examples. Rather, many variations of these embodiments and examples will be apparent to the skilled person, using the solution proposed.

For example, the circuitry may be made using CMOS technology (as used in the examples), but also bipolar or FET/HEMT or any other IC technology may be used.

The integrated circuit may be configured for storing of hard-coded data in an N×M ROM format for byte-wise reading, as is common with conventional ROMs, but could also be configured as a linear register of (N×M) bits which can be read out in parallel or serial.

The integrated circuit may be used for storing a binary code such as an identify-cation number, but it may also be used for storing any other form of data, such as a program for a microcontroller, cryptographic keys for a security application, calibration data, etc.

1. A one time programmable, immutable integrated circuit having a predetermined IC-specific N-bit binary code hard-coded into the structure of the integrated circuit, identification comprising:
a plurality of logic voltage lines
N identical bit circuits, each adapted to generate one bit of the N-bit code, the bit circuits being formed in a plurality of first lower layers of the integrated circuit, wherein each bit circuit comprises an input and an output;
N identical pull-down circuits, each electrically connecting an input of one of the N bit circuits to one of the logic voltage lines the pulldown circuits being formed in the first lower layers of the integrated circuit; and
a plurality of programmable conductive connections formed above the first lower layers, the programmable conductive connections electrically connecting an input of a selected set of the bit circuits to one of the logic voltage lines an input of all of the bit circuits being electrically connected via a respective pulldown circuit to a logic voltage line having a voltage representing a logical “0”;
wherein, for the inputs of the selected set of the bit circuits, the logic voltage line electrically connected via the respective pull-down circuit and the logic voltage line electrically connected via the respective programmable conductive connection, represent different logic levels,
wherein the electrical connections via the programmable conductive connections in conjunction with the bit circuits and the pull-down circuits, hard-code the IC-specific N-bit binary code into the integrated circuit,
and wherein the programming of said conductive connections has been performed by an etching process.

2. The integrated circuit of claim 1, wherein each one of the bit circuits has a programmable conductive connection electrically connected to the input of that bit circuit, wherein selected ones of the programmable conductive connections have been altered to break the electrical connection between the input of the respective bit circuit and the respective logic voltage line.

3. The integrated circuit of claim 2, wherein the altered programmable conductive connections have a portion removed by selective etching to break the electrical connection between the input of the respective bit circuit and the respective logic voltage line.

4. The integrated circuit of claim 2, wherein, during operation, the electrical connections formed by unaltered programmable conductive connections operate to pull the input of the respective bit circuit towards the voltage of the respective logic voltage line.

5. The integrated circuit of claim 1, wherein the selected set of bit circuits have one of the programmable conductive connections formed in a contact hole to electrically connect the input of the respective selected bit circuit and the respective logic voltage line Vss), and the remaining bit circuits do not have a programmable conductive connection formed in a contact hole.

6. The integrated circuit of claim 5, wherein, during operation, the programmable conductive connections operate to pull the input of the respective bit circuit towards the respective logic voltage line.

7. The integrated circuit of claim 1, wherein the bit circuits each comprise at least one buffer circuit implementing a memory cell of a ROM.

8. The integrated circuit of claim 1, wherein the pull-down circuits each provide a soft pull-down of the voltage at the input of the respective bit circuit towards the voltage of the first logic voltage line, which may be overridden by a stronger pull-up provided by a respective programmable conductive connection.

9. The integrated circuit of claim 1, further comprising a passivation layer formed over the plurality of first lower layers, wherein the programmable conductive connections are formed above the passivation layer, the programmable conductive connections being electrically connected to the respective bit circuits via contact holes in the passivation layer.

10. The integrated circuit of claim 1, wherein the programmable conductive connections are formed in a single layer above the passivation layer.

11. The integrated circuit of claim 1, further comprising one or more bond pads electrically connectable to the plurality of bit circuits, wherein the IC-specific N-bit binary code is readable from the one or more bond pads.

12. The integrated circuit of claim 1, wherein the selected set of bit circuits comprises fewer than N bit circuits.

13. A method for hard-coding a predetermined IC-specific N-bit binary code into the structure of an integrated circuit, the method comprising providing an integrated circuit having:
a plurality of logic voltage lines,
N identical bit circuits each adapted to generate one bit of the N-bit code, the bit circuits being formed in a plurality of first lower layers of the integrated circuit, wherein each bit circuit comprises an input and an output; and
N identical pull-down circuits each electrically connecting an input of one of the N bit circuits to one of the logic voltage lines, the pull-down circuits being formed in the first lower layers of the integrated circuit;
the method comprising the further steps of:
forming N programmable conductive connections above the first lower layers, each electrically connecting an input of one of the bit circuits to one of the logic voltage lines; and
altering selected ones of the programmable conductive connections to break the electrical connection between the input of the respective bit circuit and the respective logic voltage line,
wherein:
for the inputs of the selected set of the bit circuits, the logic voltage line electrically connected via the respective pull-down circuit and the logic voltage line electrically connected via the respective programmable conductive connection, represent different logic levels, and wherein the electrical connections via the programmable conductive connections in conjunction with the bit circuits and the pull-down circuits, hard-code the IC-specific N-bit binary code into the integrated circuit.

14. The method of claim 13, wherein altering selected ones of the programmable conductive connections comprises removing a portion of the selected programmable conductive connections by selective etching to break the electrical connection between the input of the respective bit circuit and the respective logic voltage line.

15. The method of claim 13, wherein forming the plurality of programmable conductive connections electrically connecting to an input of one of a selected set of the bit circuits comprises forming the programmable conductive connections in a contact hole.

16. A method for hard-coding a predetermined IC-specific N-bit binary code into the structure of an integrated circuit, the method comprising providing an integrated circuit having:
a plurality of logic voltage lines;
N identical bit circuits, each adapted to generate one bit of the N-bit code, the bit circuits being formed in a plurality of first lower layers of the integrated circuit, wherein each bit circuit comprises an input and an output; and
N identical pull-down circuits, each electrically connecting an input of one of the N bit circuits to one of the logic voltage lines, the pull-down circuits being formed in the first lower layers of the integrated circuit;
the method comprising the further step of:
forming a plurality of programmable conductive connections above the first lower layers, the programmable conductive connections electrically connecting the input of a selected set of the bit circuits to one of the logic voltage lines, wherein the remaining bit circuits do not have a programmable conductive connection
wherein:
for the inputs of the selected set of the bit circuits, the logic voltage line electrically connected via the respective pull-down circuit and the logic voltage line electrically connected via the respective programmable conductive connection, represent different logic levels, and wherein the electrical connections via the programmable conductive connections in conjunction with the bit circuits and the pull-down circuits, hard-code the IC-specific N-bit binary code into the integrated circuit.
